(19) United States
(12) Patent Application Publication
(10) Pub. No.: US 2006/0261247 A1
(43) Pub. Date: Nov. 23, 2006

(54) SYSTEM AND METHOD FOR IMAGE IDENTIFICATION EMPLOYED THEREBY

(75) Inventor: Mei-Ju Chen, Hsinchu Hsien (TW)

Correspondence Address: DARBY & DARBY P.C., P. O. BOX 5257, NEW YORK, NY, 10150-5257, US

(73) Assignee: Pixart Imaging Inc., Hsinchu Hsien (TW)

(21) Appl. No.: 11/381,553

(22) Filed: May 4, 2006

(30) Foreign Application Priority Data
May 10, 2005 (TW) 094115024

(51) Int. Cl. H01L 27/00

(52) U.S. Cl. 250/208.1

(57) ABSTRACT

A method for image identification is to be implemented using a target and an image sensor. The target is provided with base marks that are non-collinear and that are assigned with distinct identification codes, and an orienting mark that is disposed relative to an imaginary line interconnecting two of the base marks. The image sensor is operable to capture an image of the target that contains the base and orienting marks. The method includes the steps of: evaluating the captured image to determine spatial coordinates of the base and orienting marks; and mapping the determined spatial coordinates into vectors in order to find the orienting mark, and assigning the distinct identification codes to the base marks according to spatial relation of the base marks to the orienting mark. A system that performs the method is also disclosed.

### CROSS-REFERENCE TO RELATED APPLICATION

This application claims priority of Taiwanese application no. 094115024, filed on May 10, 2005.

### BACKGROUND OF THE INVENTION

1. Field of the Invention

This invention relates to a method for image identification and to an orientation device that generates spatial coordinates of a target aimed thereby using the method.

2. Description of the Related Art

FIG. 1 illustrates a conventional system for image identification that includes a target 90 and an orientation device 902. The target 90 is planar, is rectangular in shape, and is provided with first, second, and third light-emitting diodes 911, 912, 913 that are non-collinear and that are respectively assigned with identification codes “A”, “B”, and “C”. The first, second, and third light-emitting diodes 911, 912, 913 form an equilateral triangle where the second light-emitting diode 912 is disposed proximate to an upper side of the target 90, and where the first and third light-emitting diodes 911, 913 are disposed proximate to lower-right and lower-left corners of the target 90, respectively.

When the orientation device 902 is at a first angular position, is aimed at a target point 901 on the target imaginary line interconnecting two of the base marks. The image sensor is operable to capture an image of the target that contains the base and orienting marks. The method comprises the steps of:

A) evaluating the image captured by the image sensor to determine spatial coordinates of the base and orienting marks; and

B) mapping the spatial coordinates determined in step A) into vectors in order to find the orienting mark, and assigning the distinct identification codes to the base marks according to spatial relation of the base marks to the orienting mark.

According to another aspect of the present invention, a system for image identification comprises a target and an orientation device. The target is provided with at least three base marks that are non-collinear and that are assigned with distinct identification codes, and an orienting mark that is disposed relative to an imaginary line interconnecting two of the base marks. The orientation device includes an image sensor and a processor. The image sensor is operable so as to capture an image of the target that contains the base and orienting marks. The processor is coupled to the image sensor, and is operable so as to evaluate the image captured by the image sensor to determine spatial coordinates of the base and orienting marks, so as to map the spatial coordinates determined thereby into 90, and is operated, the orientation device 902 captures an image of the target 90 that contains light emitted by the light-emitting diodes 911, 912, 913. As illustrated in FIG. 2, spatial coordinates of the first, second and third light-emitting diodes 911, 912, 913 in the captured image correspond to spatial coordinates of the first, second and third light-emitting diodes 911, 912, 913 on the target 90, respectively. Subsequently, the orientation device 902 evaluates the image captured thereby to determine spatial coordinates of the first, second and third light-emitting diodes 911, 912, 913, and respectively assigns the identification codes “A”, “B”, and “C” to the first, second and third light-emitting diodes 911, 912, 913 according to spatial relation of the first, second, and third light-emitting diodes 911, 912, 913. Thereafter, the orientation device 902 obtains spatial coordinates of the target point 901 with reference to the identified first, second and third light-emitting diodes 911, 912, 913.

The aforementioned conventional system is disadvantageous in that when the orientation device 902 is operated after being rotated to a second angular position that is a hundred and twenty degrees from the first angular position with respect to an axis 81 perpendicular to the target 90, as illustrated in FIG. 3, the spatial coordinates of the first, second and third light-emitting diodes 911, 912, 913 in the captured image correspond to the spatial coordinates of the third, first, and second light-emitting diodes 911, 912, 913, respectively. As a result, the orientation device 902 mistakenly assigns the identification code “A” of the first light-emitting diode 911 to the third light-emitting diode 913, the identification code “B” of the second light-emitting diode 912 to the first light-emitting diode 911, and the identification code “C” of the third light-emitting diode 913 to the second light-emitting diode 912. Therefore, the spatial coordinates of the target point 901 obtained by the orientation device 902 are incorrect.

### SUMMARY OF THE INVENTION

Therefore, the object of the present invention is to provide a method for image identification, which can be employed to ensure that correct spatial coordinates of an aimed target point on a target can be obtained.

Another object of the present invention is to provide a system that is capable of obtaining correct spatial coordinates of an aimed target point on a target.

According to one aspect of the present invention, a method for image identification is to be implemented using a target and an image sensor. The target is provided with at least three base marks that are non-collinear and that are assigned with distinct identification codes, and an orienting mark that is disposed relative to an vectors in order to find the orienting mark, and so as to assign the distinct identification codes to the base marks according to spatial relation of the base marks to the orienting mark.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of a conventional system for image identification;

FIG. 2 is a schematic view of an image captured by an orientation device of the conventional system when the orientation device of the conventional system is at a first angular position;

FIG. 3 is a schematic view of an image captured by the orientation device of the conventional system when the orientation device of the conventional system is at a second angular position;

FIG. 4 is a perspective view of the first preferred embodiment of a system for image identification according to the present invention;

FIG. 5 is a flowchart to illustrate the first preferred embodiment of a method for image identification according to the present invention;

FIG. 6 is a schematic view of a captured image that contains three base marks and an orienting mark;

FIGS. 7A and 7B illustrate sub-steps of the first preferred embodiment of the method for image identification;

FIG. 8 is a perspective view of the second preferred embodiment of a system for image identification according to the present invention;

FIG. 9 is a flowchart to illustrate the second preferred embodiment of a method for image identification according to the present invention;

FIG. 10 is a schematic view of a captured image that contains four base marks and an orienting mark;

FIGS. 11A and 11B illustrate sub-steps of the second preferred embodiment of the method for image identification;

FIG. 12 is a perspective view of the third preferred embodiment of a system for image identification according to the present invention;

FIG. 13 is a flowchart to illustrate the third preferred embodiment of a method for image identification according to the present invention;

FIG. 14 is a schematic view of a captured image that contains five base marks and an orienting mark; and

FIGS. 15A and 15B illustrate sub-steps of the third preferred embodiment of the method for image identification.

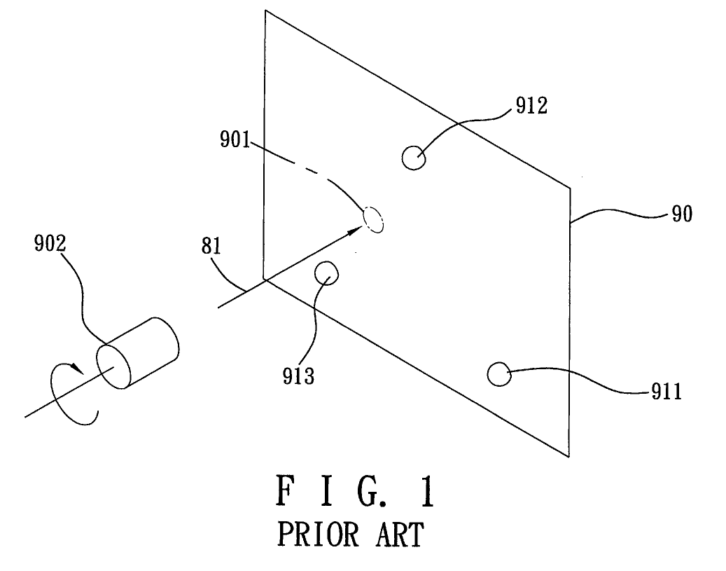

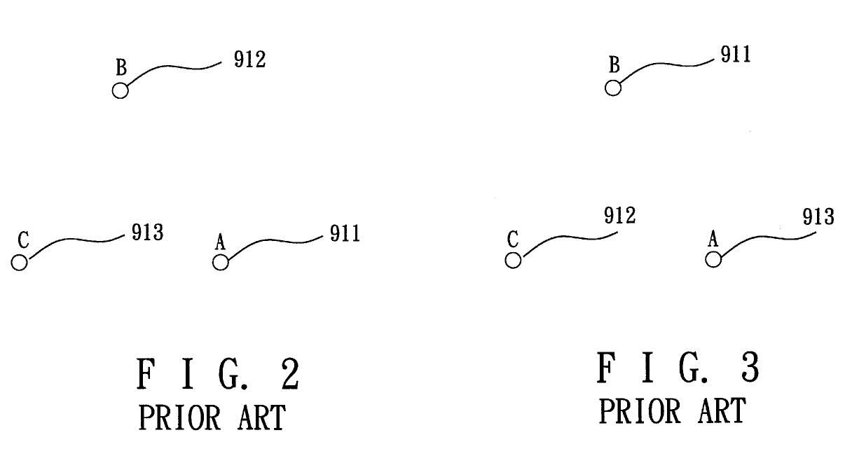

### DETAILED DESCRIPTION OF THE PREFERRED EMBODIMENTS

Before the present invention is described in greater detail, it should be noted that like elements are denoted by the same reference numerals throughout the disclosure.

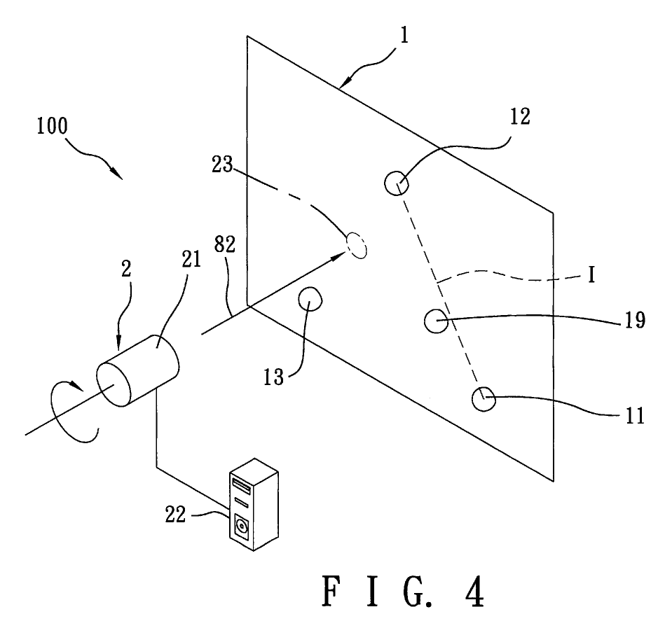

Referring to FIG. 4, the first preferred embodiment of a system 100 according to this invention is shown to include a target 1 and an orientation device 2.

It is noted that the orientation device 2 may be applied as a light gun that is typically found in video game arcades.

In this embodiment, the target 1 is planar, is generally rectangular in shape, and is provided with three base marks 11, 12, 13, and an orienting mark 19. The base marks 11, 12, 13 are non-collinear and are respectively assigned with identification codes “A”, “B”, and “C”. In this embodiment, the base marks 11, 12, 13 form an equilateral triangle where the base mark 12 is disposed proximate to an upper side of the target 1, and where the base marks 11, 13 are disposed proximate to lower-right and lower-left corners of the target 1, respectively. The orienting mark 19 is disposed proximate to an imaginary line (I) that interconnects the base marks 11, 12. In an alternative embodiment, the orienting mark 19 may be disposed along the imaginary line (I).

In this embodiment, each of the base and orienting marks 11, 12, 13, 19 is a light source. Preferably, each of the base and orienting marks 11, 12, 13, 19 is a light-emitting diode (LED).

The orientation device 2 includes an image sensor 21 and a processor 22.

The image sensor 21 of the orientation device 2 is operable so as to capture an image of the target 1 that contains the base and orienting marks 11, 12, 13, 19, and so as to convert the image captured thereby into electrical signals. In this embodiment, the image sensor 21 is a complementary metal oxide semiconductor (CMOS) light sensor.

The processor 22 of the orientation device 2 is coupled to the image sensor 21 for receiving the electrical signals generated by the latter. In this embodiment, the processor 22 of the orientation device 2 is operable so as to evaluate the image captured by the image sensor 21 in order to determine spatial coordinates of the base and orienting marks 11, 12, 13, 19, so as to map the spatial coordinates into vectors in order to find the orienting mark 19, and so as to respectively assign the identification codes “A”, “B”, and “C” to the base marks 11, 12, 13 according to spatial relation of the base marks 11, 12, 13 to the orienting mark 19, in a manner that will be described in greater detail hereinafter. As such, the processor 22 is able to obtain correct spatial coordinates of an aimed target point 23 on the target 1 irrespective of the angular position of the orientation device 2 about an axis 82.

In this embodiment, the processor 22 includes a central processing unit (CPU). In an alternative embodiment, the processor 22 may include a plurality of integrated circuits and discrete electric components. In yet another embodiment, the processor 22 may include software to be launched by a computer.

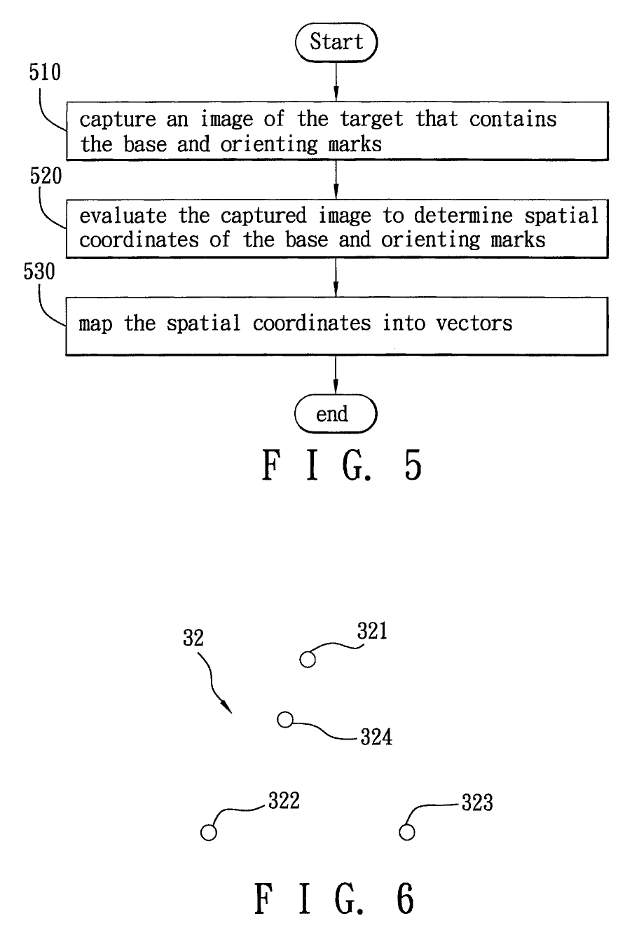

The first preferred embodiment of a method for image identification to be implemented using the aforementioned system 100 according to this invention is described with further reference to FIG. 5.

In step 510, the orientation device 2 is aimed at a target point 23 on the target 1, and is operated such that the image sensor 21 thereof is able to capture an image of the target 1 that contains the base and orienting marks 11, 12, 13, 19.

It is noted that, in this example, the orientation device 2 is at a second angular position which is angularly displaced from an ideal first angular position by an angle of a hundred and twenty degrees relative to the optical axis 82 perpendicular to the target 1.

For convenience, as illustrated in FIG. 6, the base and orienting marks 11, 12, 13, 19 in the image 32 captured by the image sensor 21 are herein referred to as the first, second and third base marks 321, 322, 323, and the orienting mark 324, respectively.

In step 520, the processor 22 evaluates the image 32 captured by the image sensor 21 to determine spatial coordinates of the first, second and third base marks 321, 322, 323, and the orienting mark 324.

In step 530, the processor 22 maps the spatial coordinates determined in step 520 into vectors in order to find the orienting mark 324, and respectively assigns the identification codes “A”, “B”, and “C” to the first, second and third base marks 321, 322, 323 according to spatial relation of the first, second and third base marks 321, 322, 323 to the orienting mark 324.

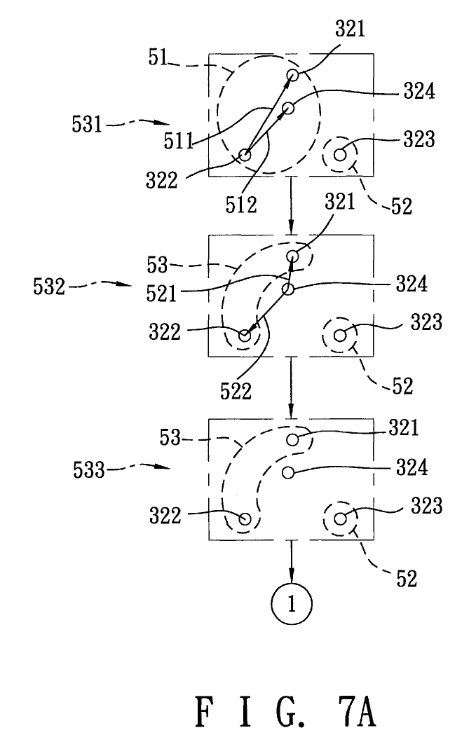

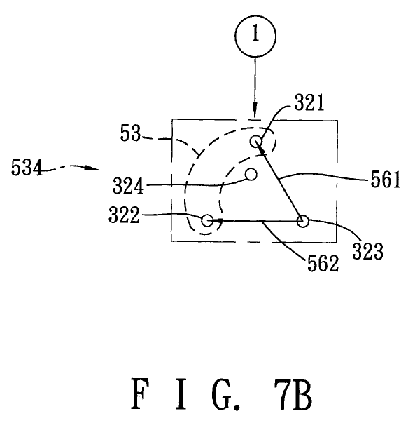

In this embodiment, step 530 includes the sub-steps shown in FIGS. 7A and 7B.

In sub-step 531, the processor 22 forms a first group 51 that includes the first and second base marks 321, 322, and the orienting mark 324, and a second group 52 that includes the third base mark 323.

Sub-step 531 includes the sub-steps of:

Sub-step 5311: finding, by performing cross product calculations, a pair of the vectors which form a smallest angle therebetween; and

Sub-step 5312: forming the first group 51 that constitutes a vertex, i.e., the second base mark 322, and a pair of vector endpoints, i.e., the first base mark 321 and the orienting mark 324, of the vectors 511, 512 found in sub-step 5311.

In sub-step 532, the processor 22 identifies the orienting mark 324 in the first group 51.

Sub-step 532 includes the sub-steps of:

Sub-step 5321: finding, by performing cross product calculations, a pair of the vectors in the first group 51 which form a largest angle therebetween;

Sub-step 5322: determining the orienting mark 324 to be at a vertex of the vectors 521, 522 determined in sub-step 5321; and

Sub-step 5323: forming the first group 51 into a subset 53 that includes the first and second base marks 321, 322.

In sub-step 533, since the second group 52 includes only the third base mark 323, the processor 22 directly assigns the identification code “C” to the third base mark 323 in the second group 52.

In sub-step 534, the processor 22 respectively assigns the identification codes “A” and “B” to the first and second base marks 321, 322 in the subset 53 of the first group 51.

Sub-step 534 includes the sub-steps of:

Sub-step 5331: finding, by performing cross product calculations, a pair of the vectors, such as the vectors 561, 562, a vertex of which is found in the second group, i.e., the third base mark 323, and vector endpoints of which are the first and second base marks 321, 322 in subset 53 of the first group 51; and

Sub-step 5332: respectively assigning the identification codes “A” and “B” to the first and second base marks 321, 322 in the subset 53 of the first group 51 according to sign of a vector product, i.e., a cross product, of the pair of the vectors 561, 562 found in sub-step 5331. That is, if the vector product of the pair of vectors 561, 562 is positive, the processor 22 determines the first base mark 321 to be at the vector endpoint that is proximate to the upper side of the target 1, and the second base mark 322 to be at the vector endpoint that is proximate to the lower-left corner of the target 1. Thereafter, the processor 22 obtains spatial coordinates of the target point 23 aimed in step 510 with reference to the identified base marks 321, 322, 323.

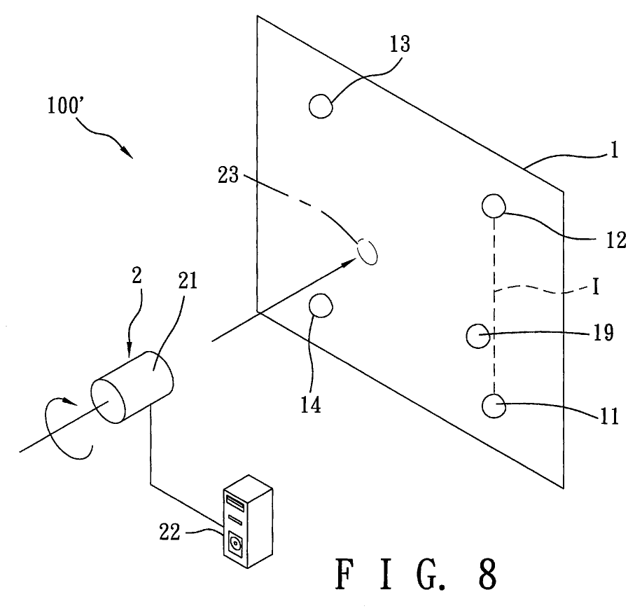

FIG. 8 illustrates the second preferred embodiment of a system 100′ according to this invention.

When compared to the previous embodiment, the target 1 is provided with four base marks 11, 12, 13, 14 that form a square where the base marks 11, 12 are disposed proximate to lower-right and upper-right corners of the target 1, respectively, and where the base marks 13, 14 are disposed proximate to upper-left and lower-left corners of the target 1, respectively. The orienting mark 19 is disposed proximate to an imaginary line (I) that interconnects the base marks 11, 12.

The second preferred embodiment of a method for image identification to be implemented using the aforementioned system 100′ according to this invention is described with further reference to FIG. 9.

In step 91, the orientation device 2 is aimed at a target point 23 on the target 1, and is operated such that the image sensor 21 thereof is able to capture an image of the target 1 that contains the base and orienting marks 11, 12, 13, 14, 19.

It is noted that, in this example, the orientation device 2 is at a third angular position which is angularly displaced from an ideal first angular position by an angle of a hundred and eighty degrees relative to the optical axis 82 perpendicular to the target 1.

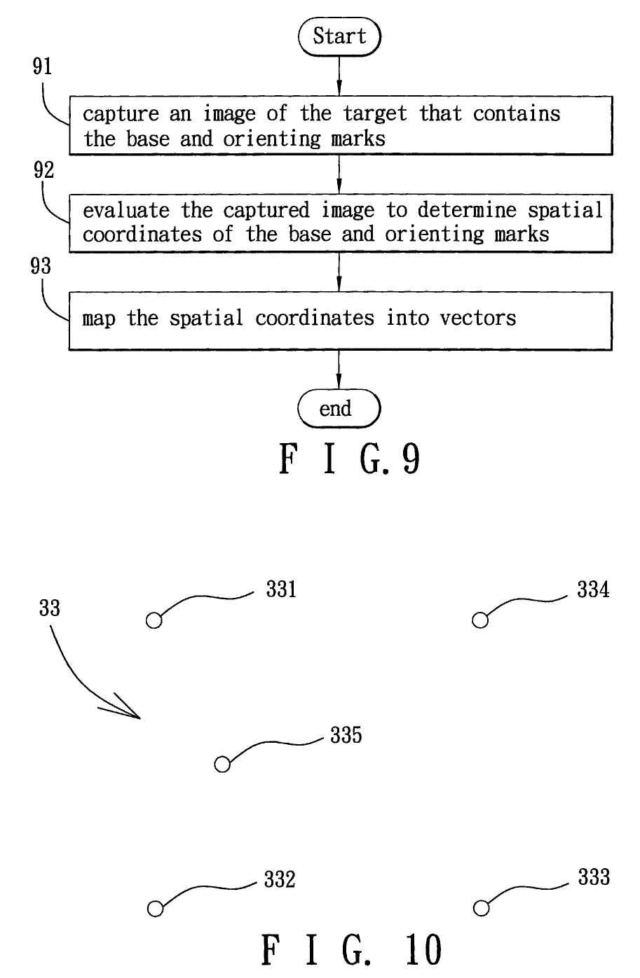

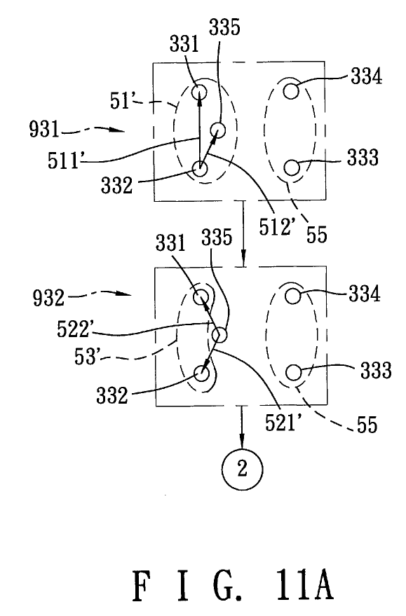

For convenience, as illustrated in FIG. 10, the base and orienting marks 11, 12, 13, 14, 19 in the image 33 captured by the image sensor 21 are herein referred to as the first, second, third and fourth base marks 331, 332, 333, 334, and the orienting mark 335, respectively.

In step 92, the processor 22 evaluates the image 33 captured by the image sensor 21 to determine spatial coordinates of the first, second, third and fourth base marks 331, 332, 333, 334, and the orienting mark 335.

In step 93, the processor 22 maps the spatial coordinates determined in step 92 into vectors in order to find the orienting mark 335, and respectively assigns the identification codes “A”, “B”, “C”, and “D” to the first, second, third and fourth base marks 331, 332, 333, 334 according to spatial relation of the first, second, third and fourth base marks 331, 332, 333, 334 to the orienting mark 335.

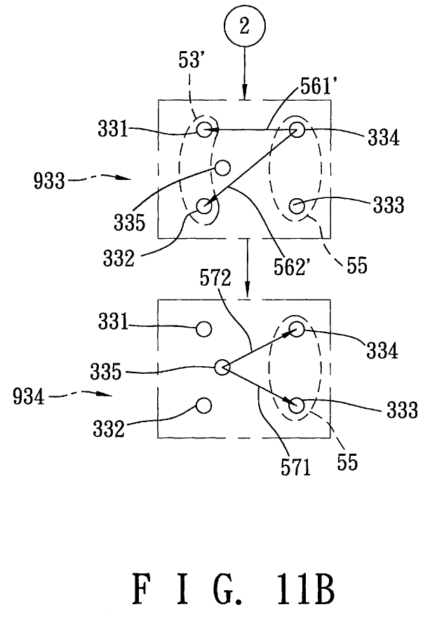

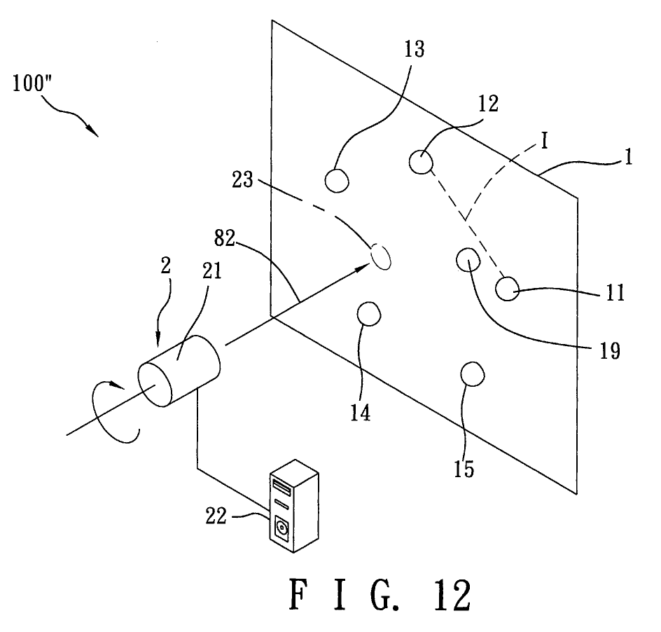

In this embodiment, step 93 includes the sub-steps shown in FIGS. 11A and 11B.

In sub-step 931, the processor 22 forms a first group 51′ that includes the first and second base marks 331, 332, and the orienting mark 335, and a second group 55 that includes the third and fourth base marks 333, 334.

Sub-step 931 includes the sub-steps of:

Sub-step 9311: finding, by performing cross product calculations, a pair of the vectors which form a smallest angle therebetween; and

Sub-step 9312: forming the first group 51′ that constitutes a vertex, i.e., the second base mark 332, and a pair of vector endpoints, i.e., the first base mark 331 and the orienting mark 335, of the vectors 511′, 512′ found in sub-step 9311.

In sub-step 932, the processor 22 identifies the orienting mark 335 in the first group 51′.

Sub-step 932 includes the sub-steps of:

Sub-step 9321: finding, by performing cross product calculations, a pair of the vectors in the first group 51′ which form a largest angle therebetween;

Sub-step 9322: determining the orienting mark 335 to be at a vertex of the vectors 521′, 522′ found in sub-step 9321; and

Sub-step 9323: forming the first group 51′ into a subset 53′ that includes the first and second base marks 331, 332.

In sub-step 933, the processor 22 respectively assigns the identification codes “A” and “B” to the first and second base marks 331, 332 in the subset 53′ of the first group 51′.

Sub-step 933 includes the sub-steps of:

Sub-step 9331: finding, by performing cross product calculations, a pair of the vectors, such as the vectors 561′, 562′, a vertex of which is found in the second group 55, such as the fourth base mark 334, and vector endpoints of which are the first and second base marks 331, 332 in the subset 53′ of the first group 51′; and

Sub-step 9332: respectively assigning the identification codes “A” and “B” to the first and second base marks 331, 332 in the subset 53′ of the first group 51′ according to sign of a vector product, i.e., cross product, of the pair of the vectors 561′, 562′ found in sub-step 9331. That is, if the vector product of the pair of vectors 561′, 562′ is positive, the processor 22 determines the first base mark 331 to be at the vector endpoint that is proximate to the upper-left corner of the target 1, and the second base mark 332 to be at the vector endpoint that is proximate to the lower-left corner of the target 1.

In sub-step 934, the processor 22 respectively assigns the identification codes “C” and “D” to the third and fourth base marks 333, 334 in the second group 55.

Sub-step 934 includes the sub-steps of:

Sub-step 9341: finding, by performing cross product calculations, a pair of the vectors, such as the vectors 571, 572, a vertex of which is found in the first group 51′, such as the orienting mark 335, and vector endpoints of which are the third and fourth base marks 333, 334 in the second group 55; and

Sub-step 9342: respectively assigning the identification codes “C” and “D” to the third and fourth base marks 333, 334 in the second group 55 according to sign of a vector product, i.e., cross product, of the pair of the vectors 571, 572 found in sub-step 9341. That is, if the vector product of the pair of vectors 571, 572 is positive, the processor 22 determines the third base mark 333 to be at the vector endpoint that is proximate to the lower-right corner of the target 1, and the fourth base mark 334 to be at the vector endpoint that is proximate to the upper-right corner of the target 1. Thereafter, the processor 22 obtains spatial coordinates of the target point 23 aimed in step 91 with reference to the identified base marks 331, 332, 333, 334.

FIG. 12 illustrates the third preferred embodiment of a system 100″ according to this invention.

When compared to the previous embodiments, the target 1 is provided with five base marks 11, 12, 13, 14, 15 that form an equilateral pentagonal shape where the base mark 12 is disposed proximate to the upper side of the target 1, where the base marks 11, 13 are disposed proximate to middle right and left sides of the target1, and where the base marks 15, 14 are disposed proximate to lower right and left sides of the target 1. The orienting mark 19 is disposed proximate to an imaginary line (I) that interconnects the base marks 11, 12.

The third preferred embodiment of a method for image identification to be implemented using the aforementioned system 100″ according to this invention is described with further reference to FIG. 13.

In step 131, the orientation device 2 is aimed at a target point 23 on the target 1, and is operated such that the image sensor 21 thereof is able to capture an image of the target 1 that contains the base and orienting marks 11, 12, 13, 14, 15, 19.

It is noted that, in this example, the orientation device 2 is at a fourth angular position which is angularly displaced from an ideal first angular position by an angle of two hundred and sixteen degrees relative to the optical axis 82 perpendicular to the target 1.

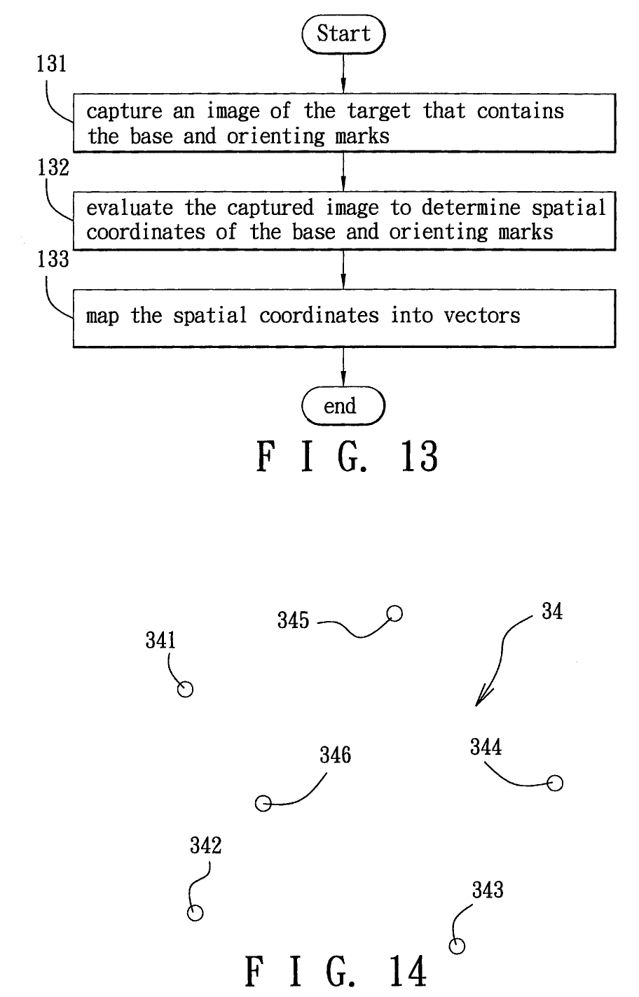

For convenience, as illustrated in FIG. 14, the base and orienting marks 11, 12, 13, 14, 15, 19 in the image 34 captured by the image sensor 21 are herein referred to as the first, second, third, fourth and fifth base marks 341, 342, 343, 344, 345, and the orienting mark 346, respectively.

In step 132, the processor 22 evaluates the image 34 captured by the image sensor 21 to determine spatial coordinates of the first, second, third, fourth and fifth base marks 341, 342, 343, 344, 345, and the orienting mark 346.

In step 133, the processor 22 maps the spatial coordinates determined in step 32 into vectors in order to find the orienting mark 346, and respectively assigns the identification codes “A”, “B”, “C”, “D”, and “E” to the first, second, third, fourth and fifth base marks 341, 342, 343, 344, 345 according to spatial relation of the first, second, third, fourth and fifth base marks 341, 342, 343, 344, 345 to the orienting mark 346.

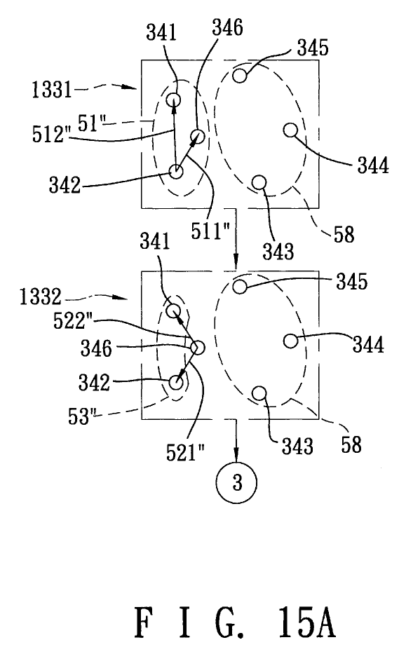

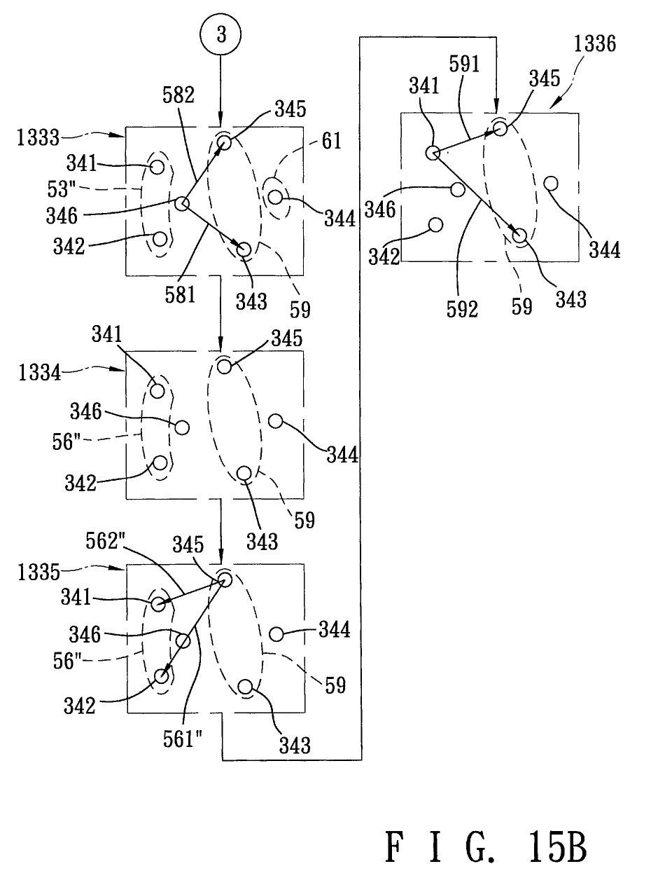

In this embodiment, step 133 includes the sub-steps shown in FIGS. 15A and 15B.

In sub-step 1331, the processor 22 forms a first group 51″ that includes the first and second base marks 341, 342, and the orienting mark 346, and a second group 58 that includes the third, fourth and fifth base marks 343, 344, 345.

Sub-step 1331 includes the sub-steps of:

Sub-step 13311: finding, by performing cross product calculations, a pair of the vectors which form a smallest angle therebetween; and

Sub-step 13312: forming the first group 51″ that constitutes a vertex, i.e., the second base mark 342, and a pair of vector endpoints, i.e., the first base mark 341 and the orienting mark 346, of the vectors 511″ , 512″ found in sub-step 3311.

In sub-step 1332, the processor 22 identifies the orienting mark 346 in the first group 51″.

Sub-step 1332 includes the sub-steps of:

Sub-step 13321: finding, by performing cross product calculations, a pair of the vectors, such as the vectors 521″, 522″, in the first group 51″ which form a largest angle therebetween;

Sub-step 13322: determining the orienting mark 346 to be at the vertex of the vectors 521″, 522″ found in sub-step 13321; and

Sub-step 13323: forming the first group 51″ into a subset 53″ that includes the first and second base marks 341, 342.

In sub-step 1333, the processor 22 forms the second group 58 into a first subset 59 that includes the third and fifth base marks 343, 345 in the second group 58, and a second subset 61 that includes the fourth base mark 344 in the second group 58.

Sub-step 1333 includes the sub-steps of:

Sub-step 13331: finding, by performing cross product calculations, a pair of the vectors, a vertex of which is found in the first group 51″, such as the orienting mark 346, and vector endpoints of which are two of the third, fourth and fifth base marks 343, 344, 345 in the second group 58, wherein the vectors to be found form a largest angle therebetween; and

Sub-step 13332: forming the first subset 59 that constitutes the vector endpoints, i.e., the third and fifth base marks 343, 345, of the vectors 581, 582 found in sub-step 13331.

In sub-step 1334, since the second subset 61 of the second group 58 includes only the fourth base mark 344, the processor 22 directly assigns the identification code “D” to the fourth base mark 344 in the second subset 61 of the second group 58.

In sub-step 1335, the processor 22 respectively assigns the identification codes “A” and “B” to the first and second base marks 341, 342 in the subset 53″ of the first group 51″.

Sub-step 1335 includes the sub-steps of:

Sub-step 13351: finding, by performing cross product calculations, a pair of the vectors, such as the vectors 561″, 562″, a vertex of which is found in the second group 58, such as the fifth base mark 345, and vector endpoints of which are the first and second base marks 341, 342 in the first group 51″; and

Sub-step 13352: respectively assigning the identification codes “A” and “B” to the first and second base marks 341, 342 in the first group 51″ according to sign of a vector product, i.e., cross product, of the pair of the vectors 561″, 562″ found in sub-step 13351. That is, if the vector product of the pair of vectors 561″, 562″ is positive, the processor 22 determines the first base mark 341 to be at the vector endpoint that is proximate to the upper-left corner of the target 1, and the second base mark 342 to be at the vector endpoint that is proximate to the lower-left corner of the target 1.

In sub-step 1336, the processor 22 respectively assigns the identification codes “C” and “E” to the third and fifth base marks 343, 345 in the first subset 59 of the second group 58.

Sub-step 1336 includes the sub-steps of:

Sub-step 13361: finding, by performing cross product calculations, a pair of the vectors, such as the vectors 591, 592, a vertex of which is found in the first group 51″, such as the first base mark 341, and vector endpoints of which are the third and fifth base marks 343, 345 in the first subset 59 of the second group 58; and Sub-step 13362: respectively assigning the identification codes “C” and “E” to the third and fifth base marks 343, 345 in the first subset 59 of the second group 58 according to sign of a vector product, i.e., cross product, of the pair of the vectors 591, 592 found in sub-step 13361. That is, if the vector product of the pair of vectors 591, 592 found in sub-step 13361 is positive, the processor 22 determines the third base mark 343 to be at the vector endpoint that is proximate to the lower-right corner of the target 1, and the fifth base mark 345 to be at the vector endpoint that is proximate to the upper-right corner of the target 1. Thereafter, the processor 22 obtains spatial coordinates of the target point 23 aimed in step 131 with reference to the identified base marks, 341, 342, 343, 344, 345.

Therefore, by taking into account spatial relation of base marks to an orienting mark in the determination of spatial coordinates of a target point, accuracy of the spatial coordinates of the target point can be ensured regardless of angular orientation of an image sensor relative to a target.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method for image identification to be implemented using a target and an image sensor, the target being provided with at least three base marks that are non-collinear and that are assigned with distinct identification codes, and an orienting mark that is disposed relative to an imaginary line interconnecting two of the base marks, the image sensor being operable to capture an image of the target that contains the base and orienting marks, the method comprising the steps of:
A) evaluating the image captured by the image sensor to determine spatial coordinates of the base and orienting marks; and
B) mapping the spatial coordinates determined in step A) into vectors in order to find the orienting mark, and assigning the distinct identification codes to the base marks according to spatial relation of the base marks to the orienting mark.

2. The method as claimed in claim 1, wherein step B) includes the sub-steps of:
B1) forming a first group that includes two of the base marks and the orienting mark, and a second group that includes remaining ones of the base marks;
B2) identifying the orienting mark in the first group; and
B3) assigning the identification codes to the base marks in the first and second groups according to spatial relation of the base marks to the orienting mark identified in sub-step B2).

3. The method as claimed in claim 2, wherein sub-step B1) includes:
a) finding a pair of the vectors which form a smallest angle therebetween; and
b) forming the first group that constitutes a vertex and a pair of vector endpoints of the vectors found in sub-step a).

4. The method as claimed in claim 2, wherein sub-step B2) includes:
a) finding a pair of the vectors in the first group which form a largest angle therebetween;
b) determining the orienting mark to be at a vertex of the vectors determined in sub-step a).

5. The method as claimed in claim 2, wherein sub-step B3) includes:
a) finding a pair of the vectors, a vertex of which is found in the second group, and vector endpoints of which are the two base marks in the first group; and
b) assigning the identification codes to the base marks in the first group according to a vector product of the pair of the vectors found in sub-step a).

6. The method as claimed in claim 2, wherein, in sub-step B1), the number of the remaining ones of the base marks in the second group is greater than two, and wherein sub-step B3) includes:
I) forming the second group into a first subset that includes two of the base marks in the second group, and a second subset that includes the remaining ones of the base marks in the second group; and
II) assigning the identification codes to the base marks in the first and second subsets.

7. The method as claimed in claim 6, wherein sub-step I) includes:
i) finding a pair of the vectors, a vertex of which is found in the first group, and vector endpoints of which are two of the base marks in the second group, the vectors to be found forming a largest angle therebetween; and
ii) forming the first subset that constitutes the vector endpoints of the vectors found in sub-step i).

8. The method as claimed in claim 6, wherein sub-step II) includes:
i) finding a pair of the vectors, a vertex of which is found in the first group, and vector endpoints of which are the two base marks in the first subset; and
ii) assigning the identification codes to the base marks in the first subset according to a vector product of the pair of the vectors found in sub-step i).

9. A system for image identification, comprising:
a target provided with at least three base marks that are non-collinear and that are assigned with distinct identification codes, and an orienting mark that is disposed relative to an imaginary line interconnecting two of the base marks; and
an orientation device including
an image sensor operable so as to capture an image of the target that contains the base and orienting marks, and
a processor coupled to the image sensor, and operable so as to evaluate the image captured by the image sensor to determine spatial coordinates of the base and orienting marks, so as to map the spatial coordinates determined thereby into vectors in order to find the orienting mark, and so as to assign the distinct identification codes to the base marks according to spatial relation of the base marks to the orienting mark.

10. The system as claimed in claim 9, wherein the orienting mark is disposed proximate to the imaginary line.

11. The system as claimed in claim 9, wherein the orienting mark is disposed along the imaginary line.

12. The system as claimed in claim 9, wherein the image sensor is a complementary metal oxide semiconductor light sensor.

13. The system as claimed in claim 9, wherein each of the base and orienting marks is a light source.

14. The system as claimed in claim 9, wherein each of the base and orienting marks is a light-emitting diode.

15. An orientation device for a system that identifies an image and that includes a target, the target being provided with at least three base marks that are non-collinear and that are assigned with distinct identification codes, and an orienting mark that is disposed relative to an imaginary line interconnecting two of the base marks, the orientation device comprising:
an image sensor adapted to capture an image of the target that contains the base and orienting marks; and
a processor coupled to the image sensor, and operable so as to evaluate the image captured by the image sensor to determine spatial coordinates of the base and orienting marks, so as to map the spatial coordinates determined thereby into vectors in order to find the orienting mark, and so as to assign the distinct identification codes to the base marks according to spatial relation of the base marks to the orienting mark.

16. A target for an image identification system, the target comprising:
at least three non-collinear base marks provided on the target and assigned with distinct identification codes; and
an orienting mark disposed relative to an imaginary line interconnecting two of the base marks.

17. The target as claimed in claim 16, wherein the orienting mark is disposed proximate to the imaginary line.

18. The target as claimed in claim 16, wherein the orienting mark is disposed along the imaginary line.

19. The target as claimed in claim 16, wherein each of the base and orienting marks is a light source.

20. The target as claimed in claim 16, wherein each of the base and orienting marks is a light-emitting diode.
